(19) United States
(12) Patent Application Publication
(10) Pub. No.: US 2025/0253262 A1
(43) Pub. Date: Aug. 7, 2025

(54) CHIP HAVING ALIGNMENT KEY AND PACKAGE STRUCTURE USING THE SAME

(71) Applicant: MACRONIX INTERNATIONAL CO., LTD., HSINCHU (TW)

(72) Inventors: Cheng-Hsien LU, Taoyuan City (TW); Ming-Hsiu LEE, Hsinchu City (TW); Dai-Ying LEE, Hsinchu County (TW)

(21) Appl. No.: 18/430,023

(22) Filed: Feb. 1, 2024

(51) Int. Cl. H01L 23/544; H01L 23/00; H01L 23/58

(52) U.S. Cl. CPC H01L 23/544; H01L 23/562; H01L 23/585; H01L 24/08; H01L 24/16; H01L 2223/54426; H01L 2224/08145; H01L 2224/16145

(57) ABSTRACT

The chip includes a device region at a substrate, a corner region at a corner of the substrate, a seal ring surrounding the device region and including a corner section adjacent the corner region, a scribe line region surrounding the seal ring and the corner region, and an alignment key disposed neighboring the seal ring. A package structure including the chip having alignment key is also disclosed.

### BACKGROUND

### Field of Invention

The present disclosure relates to a chip having an alignment key and a package structure using the same.

### Description of Related Art

In the interest of higher performance and lower cost, increased miniaturization of components and greater packaging density have been the most goals of the electric industry. The density of the IC package is primarily limited by the area available for mounting and the total height for the IC package. One of methods of increasing density is three-dimension package technology.

### SUMMARY

One of aspects of the disclosure provides a chip. The chip includes a device region at a substrate, a corner region at a corner of the substrate, a seal ring surrounding the device region and including a corner section adjacent the corner region, a scribe line region surrounding the seal ring and the corner region, and an alignment key disposed neighboring the seal ring.

In some embodiments, the seal ring includes a plurality of side sections connected by the corner section, and angles between the corner section and the side sections are greater than 90 degrees, and the alignment key is disposed in the corner region or the scribe line region.

In some embodiments, the chip further includes a stress relief region, wherein the stress relief region and the corner region are at opposite sides of the corner section, and the alignment key is disposed in the stress relief region.

In some embodiments, the chip further includes an inner spacing between the device region and the seal ring, wherein the alignment key is disposed in the inner spacing.

In some embodiments, the chip further includes an outer spacing between the seal ring and the scribe line region, wherein the alignment key is disposed in the outer spacing.

In some embodiments, the chip further includes an outer spacing between the seal ring and the scribe line region, wherein half of the alignment key is disposed in the outer spacing, and the other half of the alignment key is disposed in the scribe line region. In some embodiments, the alignment key is disposed at a top surface or a bottom surface of the substrate.

In some embodiments, the alignment key is spaced from the seal ring.

In some embodiments, the alignment key is connected to the seal ring.

In some embodiments, the scribe line region has a dicing edge, and the alignment key is spaced from the dicing edge.

In some embodiments, the scribe line region has a dicing edge, and the alignment key is connected to the dicing edge.

One of aspects of the disclosure provides a chip. The chip includes a substrate having a top surface and a bottom surface, and an alignment key disposed in the substrate and continuously extended from the top surface to the bottom surface in a single direction, wherein the alignment key is made of metal and is isolated from interconnection metal layers.

In some embodiments, the alignment key includes a triangle type pattern, a spiral type pattern, or a strip type pattern.

In some embodiments, the alignment key includes a plurality of dotted vias constructing a triangle type pattern, a spiral type pattern, or a strip type pattern.

In some embodiments, the alignment key is a through-silicon via, a through glass-via, a through-InFO via, a though-molding via, or a though-dielectric via.

One of aspects of the disclosure provides a package structure. The package structure includes a first device including a first alignment key on a top surface of the first device; and a second device bonded on the first device and including a second alignment key on a bottom surface of the second device. In a plan view, a plurality of pitches between the first alignment key and the second alignment key are identical, and the pitches are measured in at least two directions.

In some embodiments, the second alignment key is continuously extended from the bottom surface to a top surface of the second device in a single direction.

In some embodiments, the second device further includes an additional second alignment key disposed on a top surface the second device.

In some embodiments, the second device includes a device region at a substrate, a corner region at a corner of the substrate, a seal ring surrounding the device region and comprising a corner section adjacent the corner region, and a scribe line region surrounding the seal ring, wherein the second alignment key is disposed neighboring the corner section of the seal ring.

In some embodiments, the package structure further includes a third device bonded on the second device, the third device including a third alignment key on a surface of the third device. In the plan view, a plurality of pitches between the second alignment key and the third alignment key are identical, and the pitches between the second alignment key and the third alignment key are measured in at least two directions.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a partial view of a chip with alignment key according to some embodiments of the disclosure.

FIG. 2 is a partial view of a chip with alignment key according to some embodiments of the disclosure.

FIG. 3 is a partial view of a chip with alignment key according to some embodiments of the disclosure.

FIG. 4 is a partial view of a wafer including chips with alignment key according to some embodiments of the disclosure.

FIG. 5 is a partial view of a wafer including chips with alignment key according to some embodiments of the disclosure.

FIG. 6 is a partial view of a wafer including chips with alignment key according to some embodiments of the disclosure.

FIG. 7 is a cross-sectional view of a chip with alignment key according to some embodiments of the disclosure.

FIG. 8 and FIG. 9 are top views of the alignment key of FIG. 7 according to different embodiments of the disclosure.

FIG. 10A is a cross-sectional view of a package structure according to some embodiments of the disclosure.

FIGS. 10B-10D are plan views of different embodiments of the alignment keys of the package structure of FIG. 10A.

FIG. 11A is a cross-sectional view of a package structure according to some embodiments of the disclosure.

FIGS. 11B-11D are plan views of different embodiments of the alignment keys of the package structure of FIG. 11A.

FIG. 12A is a cross-sectional view of a package structure according to some embodiments of the disclosure.

FIGS. 12B-12D are plan views of different embodiments of the alignment keys of the package structure of FIG. 12A.

FIG. 13A is a schematic arrangement of a pair of conventional alignment keys and the corresponding detected signal thereof.

FIG. 13B is a schematic arrangement of a pair of conventional alignment keys having critical dimension difference issue and the corresponding detected signal thereof.

FIG. 14A is a schematic arrangement of a pair of alignment keys and the corresponding detected signal thereof according to some embodiments of the disclosure.

FIG. 14B is a schematic arrangement of a pair of alignment keys having critical dimension difference issue and the corresponding detected signal thereof according to some embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

In a three-dimension package structure, a plurality of chips and/or wafers are stacked in sequence. These chips and/or wafers are placed by using a coarse alignment process followed by a fine alignment process. The coarse alignment process includes inserting a visible light camera between the chips and/or wafers, and aligning the chips and/or wafers via the alignment keys. After the chips and/or wafers are temporarily positioned, an infrared camera is used to fine align the chips and/or wafers.

The infrared light cannot pass through metal. Therefore, each chip or wafer from bottom to top requires a restricted area determined by a metal-free design rule that prohibits metal from getting close to the alignment keys to ensure the signal capture and bonding quality. This will cause large area waste. One of the aspects of the present disclosure provides a chip with alignment key, in which the position of the alignment key does not generate waste of excess area and improves area utilization efficiency.

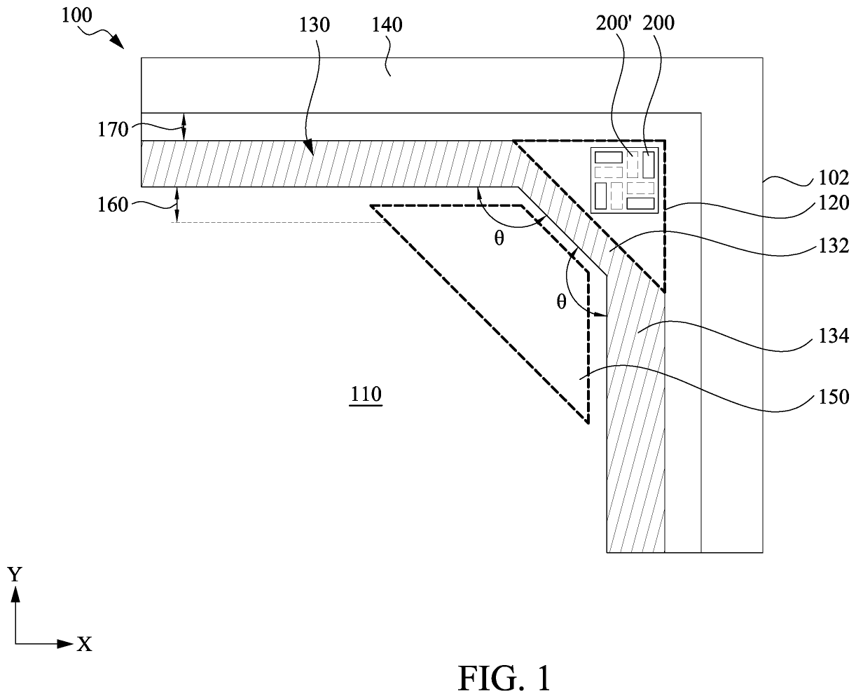

Reference is made to FIG. 1, which is a partial view of a chip with alignment key according to some embodiments of the disclosure. The chip 100 includes a device region 110 at a substrate 102, a corner region 120 at a corner of the substrate 102, a seal ring 130 surrounding the device region 110 and including a corner section 132 adjacent the corner region 120, a scribe line region 140 surrounding the seal ring 130 and the corner region 120. The chip 100 includes an alignment key 200, and the alignment key 200 is disposed neighboring the seal ring 130. Please note that the alignment key 200′ illustrated in dash lines are the pairing alignment key to the alignment key 200, and the alignment key 200′ is formed on an additional chip or wafer.

The seal ring 130 is typically formed on an inner side of dicing lines, in which the scribe line region 140 is a region being cut during dicing. The seal ring 130 is configured to protect the device region 110 from influences of external environments and to protect the integrated circuits of the device region 110 from moisture-induced degradation.

The seal ring 130 generally is formed of metal lines and connecting vias and is electrically floating and does not provide electrical connection function. The seal ring 130 includes side sections 134 connected by the corner section 132, and angles θ between the corner section 132 and the side sections 134 are greater than 90 degrees. That is, the corner region 120 adjacent the corner section 132 of the seal ring 130 has a triangle shape. The alignment key 200 of the present disclosure can be disposed in the corner region 120 to reduce the area waste.

Although there is only one the alignment key 200 illustrated in FIG. 1, the number of the alignment key 200 is preferable multiple such as more than three and arranged at the corner regions 120 of the chip, respectively. The alignment key 200 illustrated in FIG. 1 is a strip type pattern, but is not limited to, as well as the pattern of the alignment key 200 (or the alignment keys 200 together) can prevent misalignment relative to the X and Y reference axis.

In some embodiments, the chip 100 further includes a stress relief region 150 disposed at an inner side of the seal ring 130. The stress relief region 150 and the corner region 120 are at opposite sides of the corner section 132. The stress relief region 150 is a region free of circuits to provide chip corner stress relief function.

In some embodiments, the chip 100 further includes an inner spacing 160 between the device region 110 and the seal ring 130 and an outer spacing 170 between the seal ring 130 and the scribe line region 140. The inner spacing 160 and the outer spacing 170 are margin spacing to the seal ring 130 determined according to the seal ring design rule.

The aforementioned stress relief region 150, inner spacing 160, and outer spacing 170 are the regions free of circuit, thus the one or more alignment keys 200 can be disposed in the corner region 120, the scribe line region 140, the stress relief region 150, the inner spacing 160, the outer spacing 170, or combinations thereof to reduce the area waste for arranging the one or more alignment keys 200.

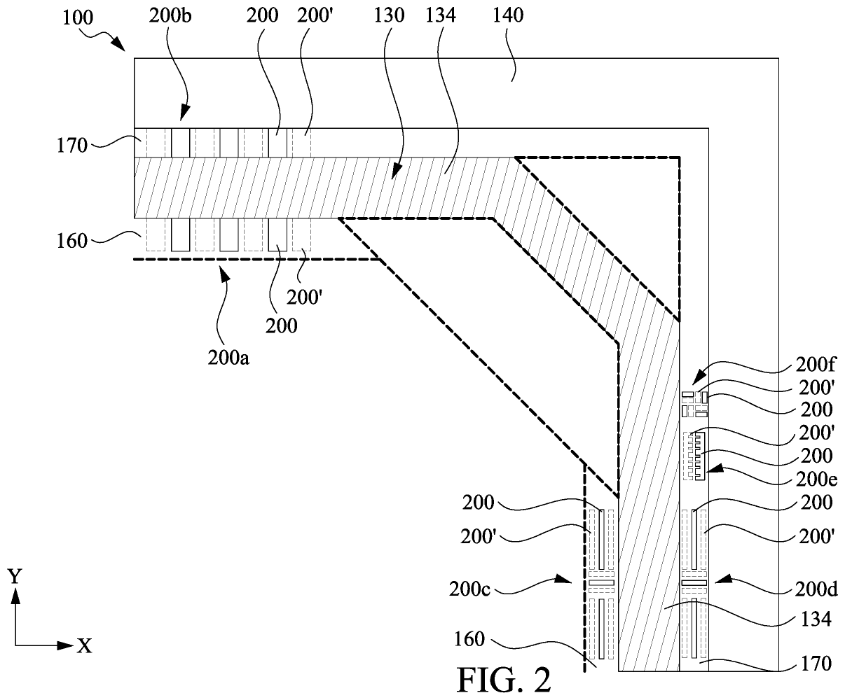

Reference is made to FIG. 2, which is a partial view of a chip with alignment key according to some embodiments of the disclosure. In some embodiments, the alignment keys 200 are disposed neighboring the seal ring 130 such as in the inner spacing 160 and/or the outer spacing 170. The pattern of the alignment keys 200 can be extended inward or outward from the seal ring 130. In some embodiments, the alignment keys 200 such as alignment keys 200a and 200b can be connected to the side sections 134 of the seal ring 130. In some other embodiments, the alignment keys 200 such as alignment keys 200c and 200d can be spaced from the side sections 134 of the seal ring 130.

In some embodiments, the alignment keys 200 can be disposed corresponding to at least two side sections 134 of the seal ring 130, and the alignment keys 200 together prevent misalignment relative to the X and Y reference axis. In the embodiments that the alignment keys 200 are disposed in both the inner spacing 160 and the outer spacing 170, the pattern of the alignment key 200 in the inner spacing 160 such as alignment keys 200a and 200c can be symmetric with the pattern of the alignment key 200 in the outer spacing 170 such as alignment keys 200b and 200d, to further alignment accuracy.

In some embodiments, the alignment keys 200 such as alignment keys 200e and 200f are disposed in either the inner spacing 160 or the outer spacing 170. The pattern of the alignment key 200e is different from the pattern of the alignment key 200f to provide more than one alignment rules for better alignment accuracy.

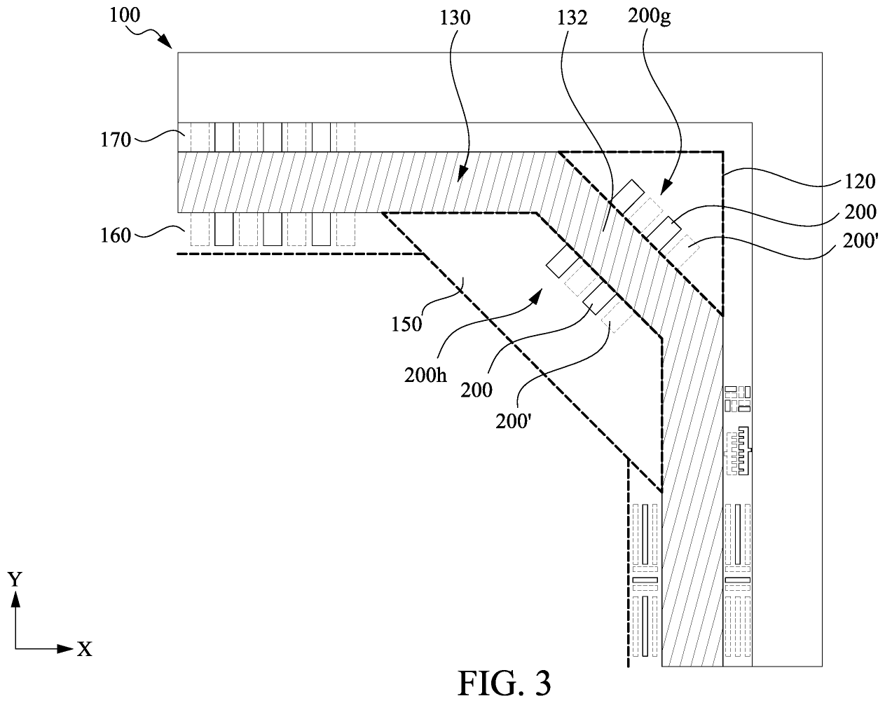

Reference is made to FIG. 3, which is a partial view of a chip with alignment key according to some embodiments of the disclosure. In some embodiments, the alignment keys 200 are disposed neighboring the seal ring 130. The alignment keys 200 such as alignment keys 200g and 200h are disposed in the corner region 120 and/or the stress relief region 150. The pattern of the alignment keys 200g and 200h can be extended inward or outward from the corner section 132 of the seal ring 130.

Due to the angle such as 45 degrees between the corner section 132 relative to the X and Y reference axis, the alignment keys 200g and 200h having pattern extended inward or outward from the corner section 132 can further provide rotation preventing function, such as the misalignment of 45-degree rotation can be extracted.

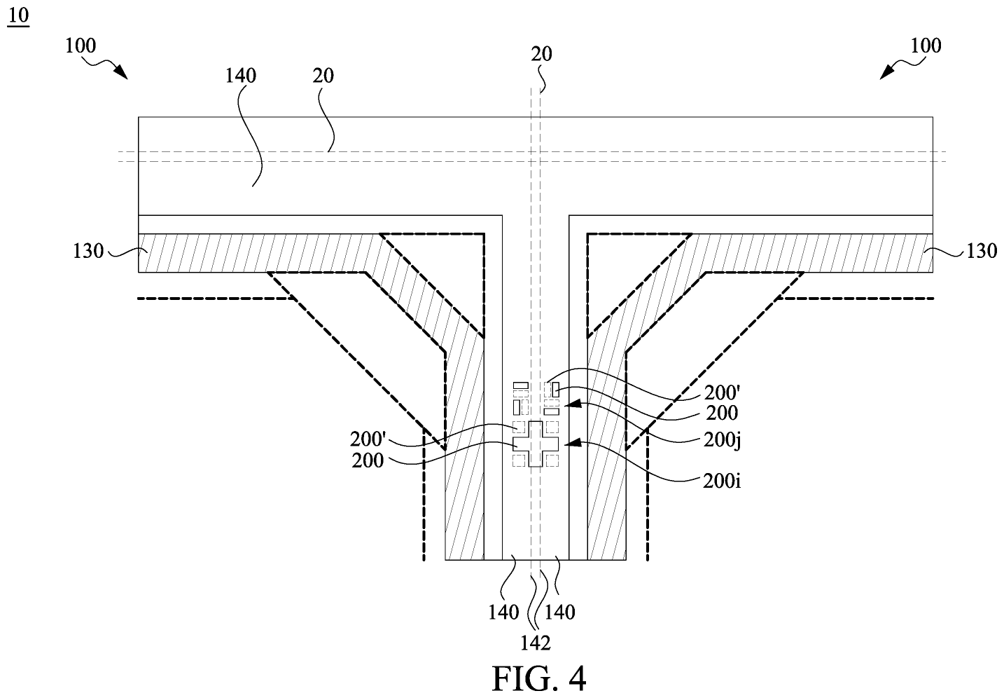

Reference is made to FIG. 4, which is a partial view of a wafer including chips with alignment key according to some embodiments of the disclosure. The wafer 10 includes a plurality of dicing lines 20, and the wafer 10 is cut through the dicing lines 20 during a dicing process, to become the chips 100. The scribe line region 140 of the chip 100 is the region that the dicing process operated on. In some embodiments, the alignment keys 200 such as alignment keys 200i and 200j are disposed in the scribe line region 140 of the chip 100, and the patterns of the alignment keys 200i and 200j are symmetric to the dicing line 20 so that the half patterns thereof still align when the alignment keys 200i and 200j are cut into two parts.

In some embodiments, the alignment key 200 such as alignment key 200i has a portion directly on the dicing line 20. Therefore, after the dicing process, the scribe line region 140 has a dicing edge 142, and the alignment key 200i is connected to the dicing edge 142.

In some embodiments, the alignment key 200 such as alignment key 200j is spaced from the dicing line 20 to prevent the alignment key 200j from being broken or avoid the residues of the alignment key 200j during the dicing process. Therefore, after the dicing process, the alignment key 200j is spaced from the dicing edge 142.

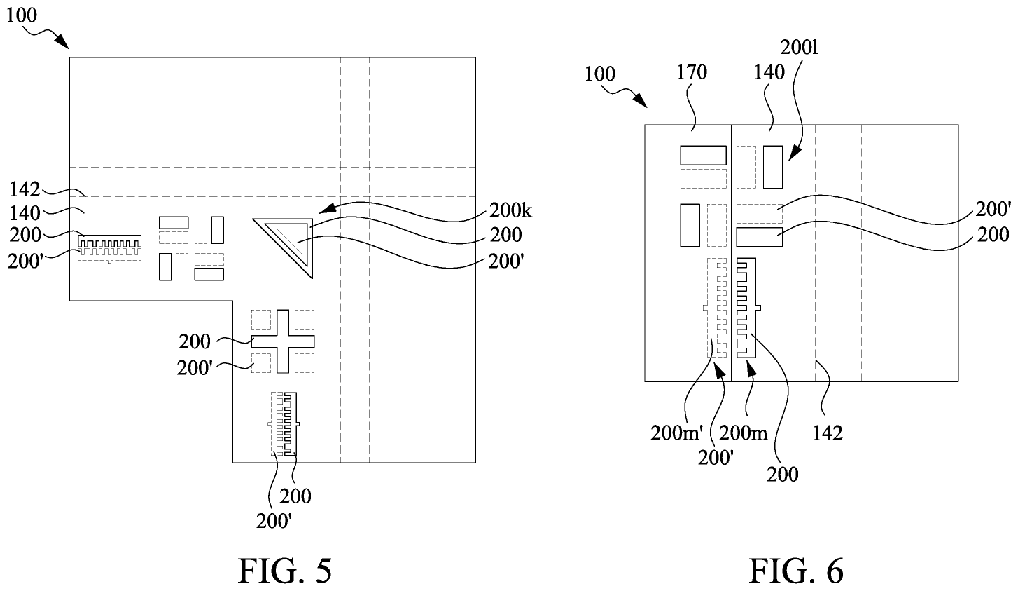

Reference is made to FIG. 5, which is a partial view of a wafer including chips with alignment key according to some embodiments of the disclosure. In some embodiments, the alignment keys 200 are disposed in the scribe line region 140 of the chip 100, and the alignment keys 200 are spaced from the dicing edge 142 and are closer to the seal ring 130 (as shown in FIG. 4) to avoid patterns of the alignment keys 200 being broken during the dicing process. In some embodiments, the number of the alignment keys 200 in the scribe line region 140 is plural, and the patterns of the alignment keys 200 can be all different, in which one of the alignment keys 200 such as the alignment key 200k has a triangle shape, and the alignment key 200k is disposed at a corner of the scribe line region 140 to identify the rotation misalign.

Reference is made to FIG. 6, which is a partial view of a wafer including chips with alignment key according to some embodiments of the disclosure. In some embodiments, the alignment keys 200 are disposed in both the scribe line region 140 and the outer spacing 170. For example, half of the alignment key 200 such as the alignment key 200l is disposed in the scribe line region 140, and the other half of the alignment key 200l is disposed in the outer spacing 170. Alternatively, the alignment key 200 such as the alignment key 200m is disposed in the scribe line region 140, and the pairing alignment key 200m′ which is disposed at another chip or wafer is disposed in its outer spacing 170. The area utilization efficiency of arranging the alignment keys 200 can be further improved.

The aforementioned alignment keys 200 are configured to align the chips and/or wafers before the chips and/or wafers are bonded. The aforementioned alignment keys 200 are formed at the top surface and the bottom surface of the chips and/or wafers.

Additionally, alignment keys at the top surface and the bottom surface of the single chip should be also made precisely to ensure bonding accuracy. However, photolithography process is suffered from pattern overlay and/or critical dimension difference of photolithographing different layers, which leads to blurring or misalignment of the alignment keys at the top surface and the bottom surface of the single chip, resulting in lower bonding accuracy. Therefore, one of the aspects of the present disclosure provides a chip with alignment key having exactly the same shape and position.

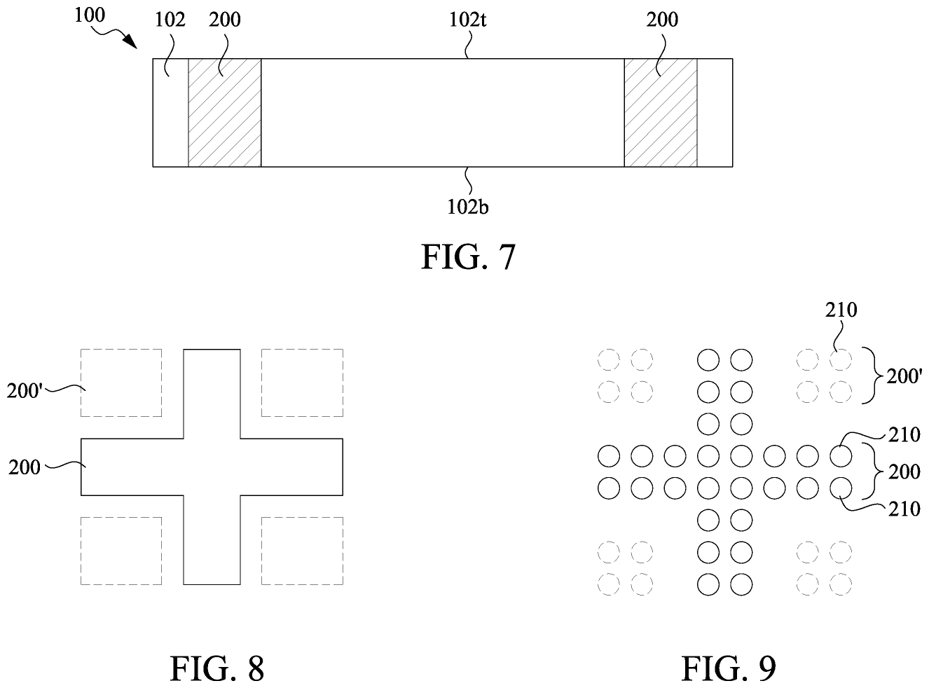

Reference is made to FIG. 7, which is a cross-sectional view of a chip with alignment key according to some embodiments of the disclosure. In some embodiments, the chip 100 includes a substrate 102 having a top surface 102t and a bottom surface 102b opposite to each other. The alignment keys 200 are formed continuously extended from the top surface 102t to the bottom surface 102b of the chip 100 in a single direction so that the shape and the position of the alignment keys 200 can be continuously maintained between the top surface 102t and the bottom surface 102b of the chip 100. The alignment keys 200 straightly penetrate the substrate 102, and the shape and the position of the alignment keys 200 are exactly the same at the top surface 102t and the bottom surface 102b. The alignment keys 200 that straightly penetrate the substrate 102 are formed by a single expose and develop process such that the problem of pattern overlay and/or critical dimension difference of patterns at different layers due to photolithography process can be prevented.

The alignment keys 200 are made of infrared light shielding material such as metal. The alignment keys 200 are electrically floating and do not provide electrical connection function. The alignment keys 200 are isolated from interconnection metal layers. Namely, the alignment keys 200 are electrically isolated and physically isolated from other interconnection metal layers. The interconnection metal layers include but not limited to, metal layers and/or metal lines that interconnect the circuits and/or components at different levels and inter-layer vias that interconnect the metal layers and/or metal lines.

Additionally, the alignment keys 200 that penetrate the substrate 102 are also isolated from bonding pads that utilized to communicate to external components. Thus the image identifying result of the alignment keys 200 would not be affected by the shielding from the bonding pads and the solders thereon. In some embodiments, the alignment keys 200 penetrating the substrate 102 not only provide alignment function, but also provide thermal dissipating function to the chip 100.

The position of the alignment key 200 that continuously extended from the top surface 102t to the bottom surface 102b of the chip 100 in a single direction can be placed as anyone of the embodiments as discussed in FIGS. 1-6. The substrate 102 can be a semiconductor substrate such as a Si substrate so that the alignment key 200 can be through-silicon via (TSV) type. The substrate 102 can be a glass substrate so that the alignment key 200 can be regarded as a through glass-via (TGV). The alignment key 200 can be formed at an integrated fan out (InFO) region of the chip 100 so that the alignment key 200 can be regarded as a through-InFO via (TIV). The alignment key 200 can be formed at a molding compound region of the chip 100 so that the alignment key 200 can be regarded as a though-molding via (TMV). The alignment key 200 can be formed at a dielectric region of the chip 100 so that the alignment key 200 can be regarded as a though-dielectric via (TDV).

Reference is made to FIG. 8 and FIG. 9, which are top views of the alignment key of FIG. 7 according to different embodiments of the disclosure. In some embodiments, the alignment key 200 is a solid pattern, and the corresponding paring alignment key 200′ is also a solid pattern, as shown in FIG. 8. The pattern of the alignment key 200 can be a triangle type pattern, a spiral type pattern, or a strip type pattern.

In some other embodiments, the alignment key 200 includes a plurality of dotted vias 210, and the dotted vias 210 construct the pattern. The corresponding paring alignment key 200′ is also constructed by dotted vias 210, as shown in FIG. 9. The pattern of the alignment key 200 can be a triangle type pattern, a spiral type pattern, or a strip type pattern constructed by the dotted vias 210. The alignment key 200 having pattern constructed by dotted vias 210 can be easily integrated in current semiconductor processes and has high fabrication precision. The optical analysis result of using the alignment key 200 of FIG. 9 can be equivalent to the optical analysis result of using the alignment key 200 of FIG. 8 by algorithm.

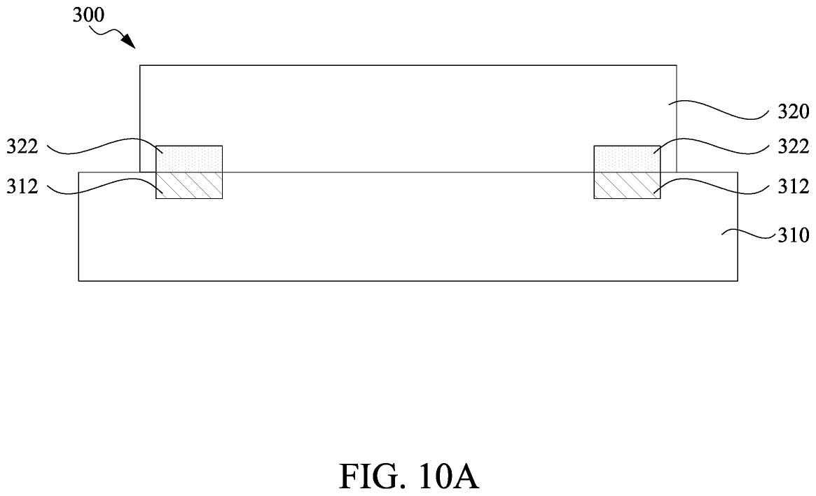

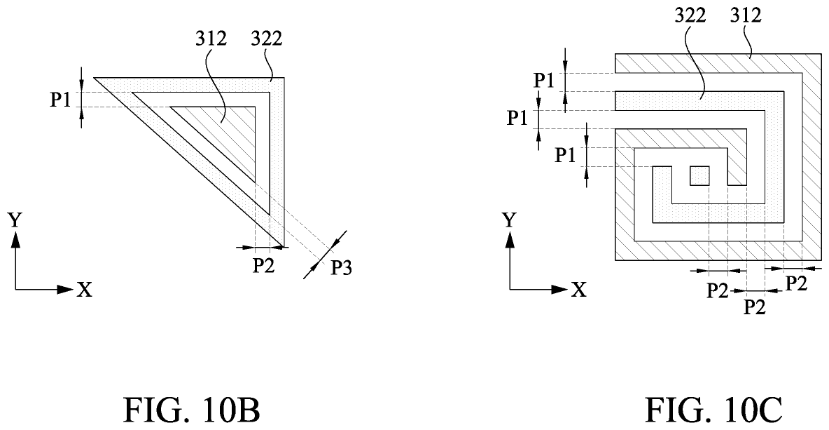

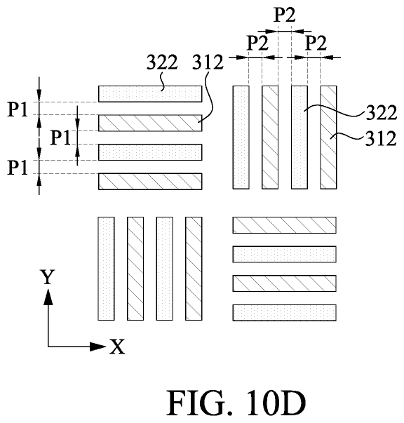

Reference is made to FIG. 10A, which is a cross-sectional view of a package structure according to some embodiments of the disclosure. The package structure 300 includes a wafer 310 and a first chip 320 bonded on the wafer 310. The wafer 310 and the first chip 320 can be bonded by a hybrid bonding, a μ-bump bonding, or other bonding methods.

The wafer 310 includes a first alignment key 312 on a top surface of the wafer 310, and the first chip 320 includes a second alignment key 322 on a bottom surface of the first chip 320. The position of the second alignment key 322 can be placed as anyone of the embodiments discussed in FIGS. 1-6. In some embodiments, the second alignment key 322 can be disposed on both top surface and the bottom surface of the first chip 320. In some other embodiments, as discussed in FIG. 7, the second alignment key 322 can be continuously extended from the bottom surface to the top surface of the first chip 320, and the second alignment key 322 can be a solid pattern or a dotted via pattern. In some embodiments, the first alignment key 312 and the second alignment key 322 not only serve positioning function, but also serve as bonding points of hybrid bonding the wafer 310 and the first chip 320.

Reference is made to FIGS. 10B-10D, which are plan views of different embodiments of the alignment keys of the package structure of FIG. 10A. In the plan view of FIG. 10B, the patterns of the first alignment key 312 and the second alignment key 322 are triangle type patterns, and the pitches P1, P2, and P3 between the first alignment key 312 and the second alignment key 322 are identical. The pitches P1, P2, and P3 are measured at least in two directions. For example, the pitches P1 and P2 are measured in the X and Y direction to prevent misalignment relative to the X and Y reference axis, and the pitches P3 are measured such as in 45 degrees relative to the X and Y direction to further prevent misalignment of 45-degree rotation.

In the plan view of FIG. 10C, the patterns of the first alignment key 312 and the second alignment key 322 are spiral type patterns. The spiral type patterns can be circular spirals, quadrilateral spirals, or polygonal spirals. The pitches P1 and P2 between the first alignment key 312 and the second alignment key 322 are identical and are measured in at least in two directions such as measured in the X and Y direction to prevent misalignment relative to the X and Y reference axis. In some embodiments, the center of the alignment keys such as center of the second alignment key 322 is a dot (for the circular spirals) or a rectangle (for the quadrilateral spirals).

In the plan view of FIG. 10D, the patterns of the first alignment key 312 and the second alignment key 322 are strip type patterns. The pitches P1 and P2 between the first alignment key 312 and the second alignment key 322 are identical and are measured in at least in two directions such as measured in the X and Y direction to prevent misalignment relative to the X and Y reference axis between the wafer 310 and the first chip 320 (see FIG. 10A). In some embodiments, the strips of the first alignment key 312 and the strips of the second alignment key 322 are alternately arranged. The strips of the first alignment key 312 and the second alignment key 322 are separated in four groups, in which the two groups of strips of diagonal of the four groups are extended in vertical direction, and the other two groups of strips are extended in horizontal direction, for easy identifying.

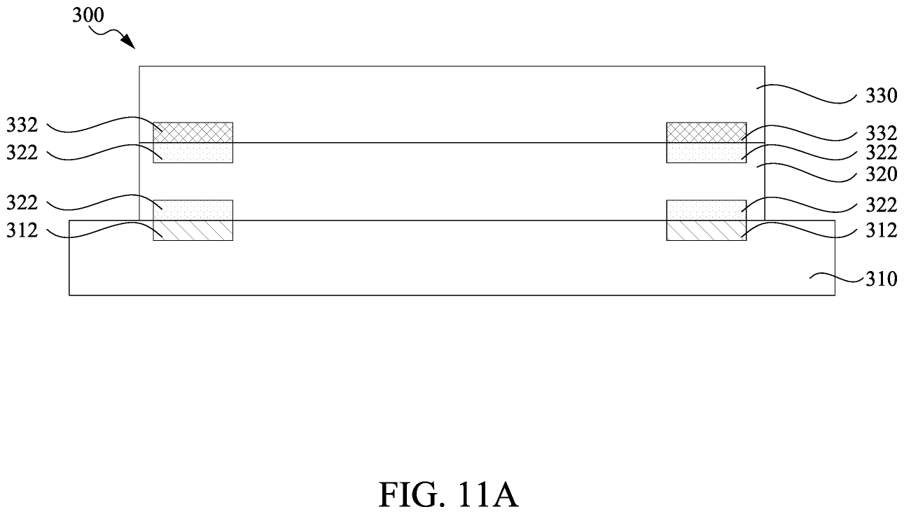

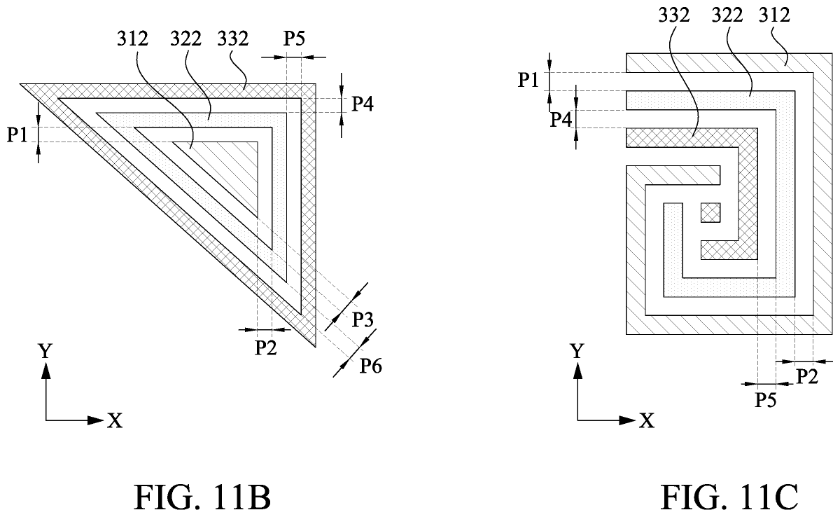

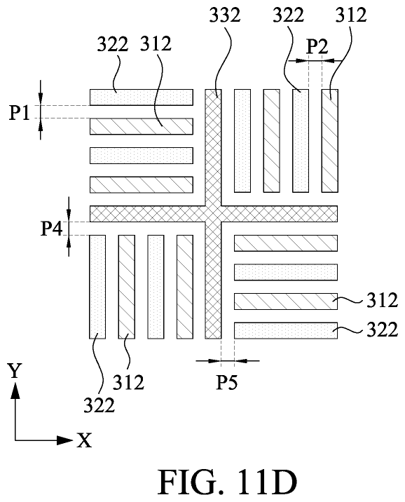

Reference is made to FIG. 11A, which is a cross-sectional view of a package structure according to some embodiments of the disclosure. The package structure 300 includes a wafer 310, a first chip 320 bonded on the wafer 310, and a second chip 330 bonded on the first chip 320. The wafer 310, the first chip 320, and the second chip 330 can be bonded by a hybrid bonding, a μ-bump bonding, or other bonding methods.

In some embodiments, the wafer 310 includes a first alignment key 312 on a top surface of the wafer 310, the first chip 320 includes second alignment keys 322 on a bottom surface and a top surface of the first chip 320, and the second chip 330 includes a third alignment key 332 on a bottom surface of the second chip 330, and the position and the shape of the second alignment keys 322 on the bottom surface and the top surface of the first chip 320 are identical.

The position of the second alignment keys 322 and the third alignment key 332 can be placed as anyone of the embodiments discussed in FIGS. 1-6. In some other embodiments, as discussed in FIG. 7, the second alignment key 322 can be continuously extended from the bottom surface to the top surface of the first chip 320 in a single direction, such that the position and the shape of the second alignment key 322 are remained identical, and the problem of pattern overlay and/or critical dimension difference of patterns at different layers due to photolithography process can be prevented. The second alignment key 322 and the third alignment key 332 can be solid patterns or dotted via patterns. In some embodiments, the first alignment key 312, the second alignment key 322, and the third alignment key 332 not only serve positioning function, but also serve as bonding points of hybrid bonding the wafer 310, the first chip 320, and the second chip 330.

Reference is made to FIGS. 11B-11D, which are plan views of different embodiments of the alignment keys of the package structure of FIG. 11A. In the plan view of FIG. 11B, the patterns of the first alignment key 312, the second alignment key 322, and the third alignment key 332 are triangle type patterns. The second alignment key 322 can be disposed between the first alignment key 312 and the third alignment key 332. The pitches P1, P2, and P3 between the first alignment key 312 and the second alignment key 322 are identical. The pitches P4, P5, and P6 between the second alignment key 322 and the third alignment key 332 are identical. The pitches P1, P2, and P3 are measured at least in two directions, and the pitches P4, P5, and P6 are measured at least in two directions. For example, the pitches P1, P2, P4, and P5 are measured in the X and Y direction to prevent misalignment relative to the X and Y reference axis, and the pitches P3 and P6 are measured such as in 45 degrees relative to the X and Y direction to further prevent misalignment of 45-degree rotation.

In the plan view of FIG. 11C, the patterns of the first alignment key 312, the second alignment key 322, and the third alignment key 332 are spiral type patterns. The spiral type patterns can be circular spirals, quadrilateral spirals, or polygonal spirals. The pitches P1 and P2 between the first alignment key 312 and the second alignment key 322 are identical. The pitches P4 and P5 between the second alignment key 322 and the third alignment key 332 are identical. The pitches P1, P2, P4, and P5 are measured at least in two directions such as measured in the X and Y direction to prevent misalignment relative to the X and Y reference axis. In some embodiments, the center of the alignment keys such as center of the third alignment key 332 is a dot (for the circular spirals) or a rectangle (for the quadrilateral spirals).

In the plan view of FIG. 11D, the patterns of the first alignment key 312, the second alignment key 322, and the third alignment key 332 are strip type patterns. The pitches P1 and P2 between the first alignment key 312 and the second alignment key 322 are identical and are measured in at least in two directions such as measured in the X and Y direction to prevent misalignment relative to the X and Y reference axis between the wafer 310 and the first chip 320 (as shown in FIG. 11A). The pitches P4 and P5 between the second alignment key 322 and the third alignment key 332 are identical and are measured in at least in two directions such as measured in the X and Y direction to prevent misalignment relative to the X and Y reference axis between the first chip 320 and the second chip 330 (as shown in FIG. 11A).

In some embodiments, the strips of the first alignment key 312 and the strips of the second alignment key 322 are alternately arranged. The strips of the first alignment key 312 and the second alignment key 322 are separated in four groups, in which the two groups of strips of diagonal of the four groups are extended in vertical direction, and the other two groups of strips are extended in horizontal direction, for easy identifying. The strips of the third alignment key 332 is a cross shape and is placed between the four groups of the strips of the first alignment key 312 and the strips of the second alignment key 322.

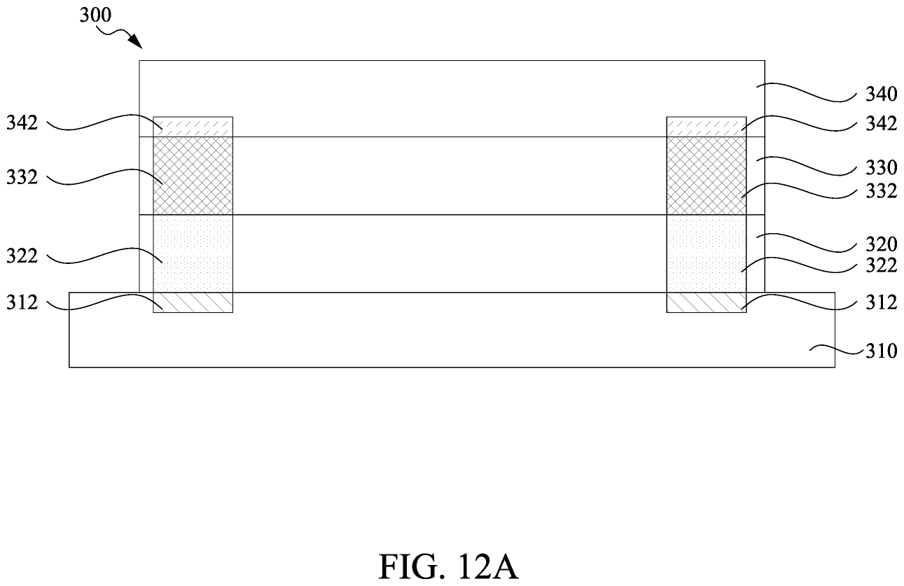

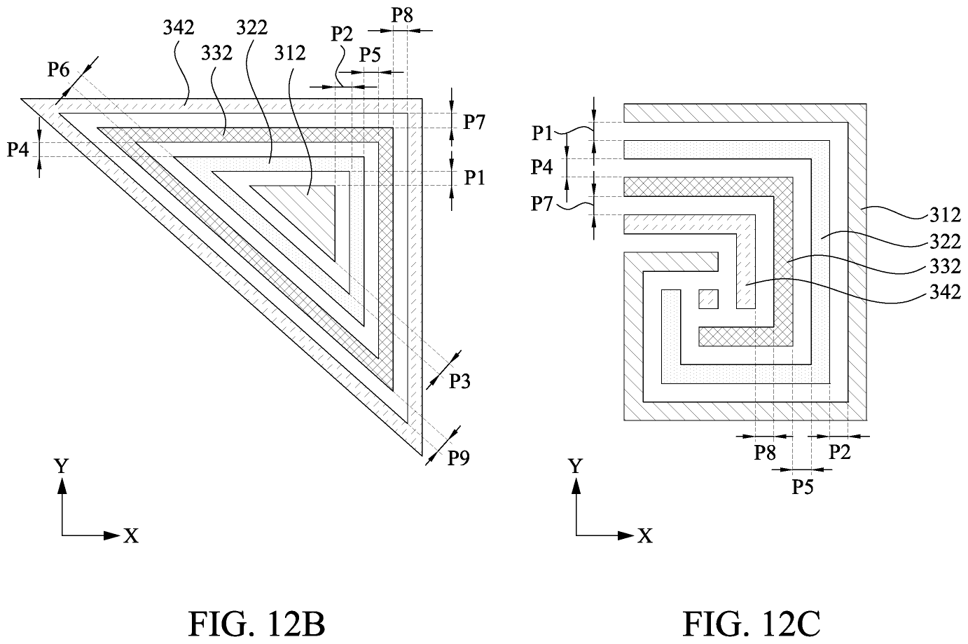

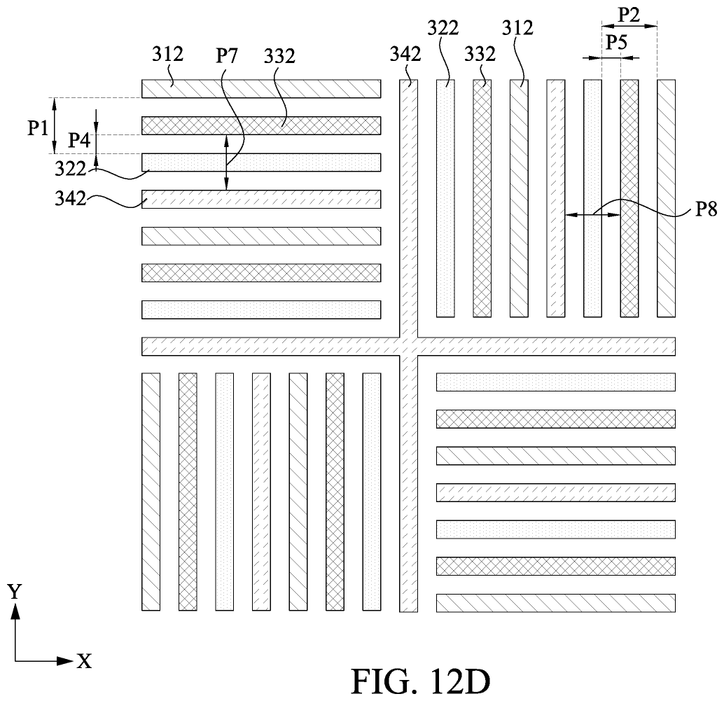

Reference is made to FIG. 12A, which is a cross-sectional view of a package structure according to some embodiments of the disclosure. The package structure 300 includes a wafer 310, a first chip 320 bonded on the wafer 310, a second chip 330 bonded on the first chip 320, and a third chip 340 bonded on the second chip 330. The wafer 310, the first chip 320, the second chip 330, and the third chip 340 can be bonded by a hybrid bonding, a μ-bump bonding, or other bonding methods.

In some embodiments, the wafer 310 includes a first alignment key 312 on a top surface of the wafer 310, the first chip 320 includes a second alignment key 322 continuously extends from a bottom surface to a top surface of the first chip 320 in a single direction, the second chip 330 includes a third alignment key 332 continuously extends from a bottom surface to a top surface of the second chip 330 in a single direction, and the third chip 340 includes a fourth alignment key 342 on a bottom surface of the third chip 340. The second alignment key 322 and the third alignment key 332 respectively penetrate the first chip 320 and the second chip 330 in a single direction, such that the position and the shape of the second alignment key 322 and the third alignment key 332 at top and bottom surfaces of the first chip 320 and the second chip 330 are remained identical, and the problem of pattern overlay and/or critical dimension difference of patterns at different layers due to photolithography process can be prevented. The second alignment key 322 and the third alignment key 332 can be a solid pattern or a dotted via pattern. The position of the second alignment key 322, the third alignment key 332, and the fourth alignment key 342 can be placed as anyone of the embodiments discussed in FIGS. 1-6. In some other embodiments, the second alignment keys 322 and the third alignment keys 332 can be disposed on both the bottom surfaces and the top surfaces of the first chip 320 and the second chip 330, respectively.

Reference is made to FIGS. 12B-12D, which are plan views of different embodiments of the alignment keys of the package structure of FIG. 12A. In the plan view of FIG. 12B, the patterns of the first alignment key 312, the second alignment key 322, the third alignment key 332, and the fourth alignment key 342 are triangle type patterns. The second alignment key 322 can be disposed between the first alignment key 312 and the third alignment key 332, and the third alignment key 332 can be disposed between the second alignment key 322 and the fourth alignment key 342. The pitches P1, P2, and P3 between the first alignment key 312 and the second alignment key 322 are identical. The pitches P4, P5, and P6 between the second alignment key 322 and the third alignment key 332 are identical. The pitches P7, P8, and P9 between the third alignment key 332 and the fourth alignment key 342 are identical. The pitches P1, P2, and P3 are measured at least in two directions, the pitches P4, P5, and P6 are measured at least in two directions, and the pitches P7, P8, and P9 are measured at least in two directions. For example, the pitches P1, P2, P4, P5, P7, and P8 are measured in the X and Y direction to prevent misalignment relative to the X and Y reference axis, and the pitches P3, P6, and P9 are measured such as in 45 degrees relative to the X and Y direction to further prevent misalignment of 45-degree rotation.

In the plan view of FIG. 12C, the patterns of the first alignment key 312, the second alignment key 322, the third alignment key 332, and the fourth alignment key 342 are spiral type patterns. The spiral type patterns can be circular spirals, quadrilateral spirals, or polygonal spirals. The pitches P1 and P2 between the first alignment key 312 and the second alignment key 322 are identical. The pitches P4 and P5 between the second alignment key 322 and the third alignment key 332 are identical. The pitches P7 and P8 between the third alignment key 332 and the fourth alignment key 342 are identical. The pitches P1, P2, P4, P5, P7, and P8 are measured at least in two directions such as measured in the X and Y direction to prevent misalignment relative to the X and Y reference axis. In some embodiments, the center of the alignment keys such as center of the fourth alignment key 342 is a dot (for the circular spirals) or a rectangle (for the quadrilateral spirals).

In the plan view of FIG. 12D, the patterns of the first alignment key 312, the second alignment key 322, the third alignment key 332, and the fourth alignment key 342 are strip type patterns. The pitches P1 and P2 between the first alignment key 312 and the second alignment key 322 are identical and are measured in at least in two directions such as measured in the X and Y direction to prevent misalignment relative to the X and Y reference axis between the wafer 310 and the first chip 320 (as shown in FIG. 12A). The pitches P4 and P5 between the second alignment key 322 and the third alignment key 332 are identical and are measured in at least in two directions such as measured in the X and Y direction to prevent misalignment relative to the X and Y reference axis between the first chip 320 and the second chip 330 (as shown in FIG. 12A). The pitches P7 and P8 between the third alignment key 332 and the fourth alignment key 342 are identical and are measured in at least in two directions such as measured in the X and Y direction to prevent misalignment relative to the X and Y reference axis between the second chip 330 and the third chip 340 (as shown in FIG. 12A).

In some embodiments, the strips of the first alignment key 312, the second alignment key 322, the third alignment key 332, and the fourth alignment key 342 are alternately arranged such that the strips as a whole are periodical. The strips of the first alignment key 312, the second alignment key 322, the third alignment key 332, and the fourth alignment key 342 are separated in four groups, in which the two groups of strips of diagonal of the four groups are extended in vertical direction, and the other two groups of strips are extended in horizontal direction, for easy identifying. The fourth alignment key 342 further includes a cross shape strip and is placed between the four groups of the strips.

In some embodiments, the two groups of strips at diagonal can be symmetric to the cross shape strip of the fourth alignment key 342. In each group, the strip of the third alignment key 332 is between the strip of the first alignment key 312 and the strip of the second alignment key 322, the strip of the second alignment key 322 is between the strip of the third alignment key 332 and the strip of the fourth alignment key 342, and the strip of the fourth alignment key 342 is between the strip of the second alignment key 322 and the strip of the first alignment key 312.

Although the devices of the package structures 300 discussed above are combinations of wafer and chips, but the package structure 300 is not limited in a wafer-to-chip package structure. In some other embodiments, the package structure of the disclosure can be a wafer-to-wafer package structure or a chip-to-chip package structure.

The arrangements of the alignment keys as discussed in FIGS. 10B-10D, 11B-11D, and 12B-12D not only provide good alignment but also improve signal analysis efficiency of the alignment.

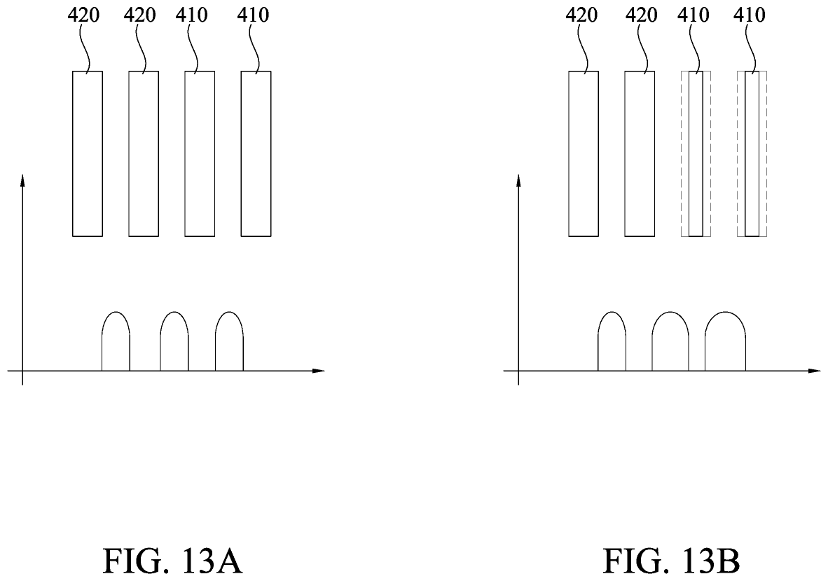

Reference is made to FIG. 13A and FIG. 13B. FIG. 13A is a schematic arrangement of a pair of conventional alignment keys and the corresponding detected signal thereof, in which the first alignment key 410 is disposed aside the second alignment key 420. FIG. 13B is a schematic arrangement of a pair of conventional alignment keys and the corresponding detected signal thereof, in which the first alignment key 410 is disposed aside the second alignment key 420, and the first alignment key 410 has critical dimension difference issue. Comparing FIG. 13A and FIG. 13B, the signal of FIG. 13A is periodic and has same width. However, the signal of FIG. 13B is periodic and has different widths, and that needs extra work for signal analysis.

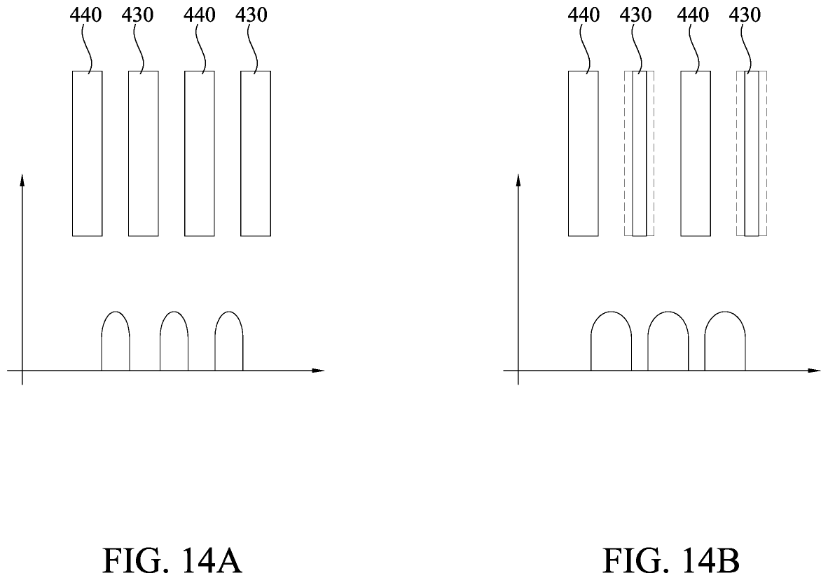

Reference is made to FIG. 14A and FIG. 14B. FIG. 14A is a schematic arrangement of a pair of alignment keys and the corresponding detected signal thereof according to some embodiments of the disclosure, in which the pitches between the first alignment key 430 and the second alignment key 440 are identical. FIG. 14B is a schematic arrangement of a pair of alignment keys and the corresponding detected signal thereof according to some embodiments of the disclosure, in which the pitches between the first alignment key 430 and the second alignment key 440 are identical, and the first alignment key 430 has critical dimension difference issue. Comparing FIG. 14A and FIG. 14B, the signal of FIG. 14A is periodic and has same width, and the signal of FIG. 14B remains having same width even if the first alignment key 430 has critical dimension difference issue.

The design of identical pitches between the first alignment key 430 and the second alignment key 440 can survive from the critical dimension difference issue and does not need extra work for signal analysis. The signal analysis step of the alignment process can be more efficiency.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims and their equivalents.

What is claimed is:

1. A chip comprising:
a device region at a substrate;
a corner region at a corner of the substrate;
a seal ring surrounding the device region and comprising a corner section adjacent the corner region;
a scribe line region surrounding the seal ring and the corner region; and
an alignment key disposed neighboring the seal ring.

2. The chip of claim 1, wherein the seal ring comprises a plurality of side sections connected by the corner section, and angles between the corner section and the side sections are greater than 90 degrees, and the alignment key is disposed in the corner region or the scribe line region.

3. The chip of claim 1, further comprising a stress relief region, wherein the stress relief region and the corner region are at opposite sides of the corner section, and the alignment key is disposed in the stress relief region.

4. The chip of claim 1, further comprising an inner spacing between the device region and the seal ring, wherein the alignment key is disposed in the inner spacing.

5. The chip of claim 1, further comprising an outer spacing between the seal ring and the scribe line region, wherein the alignment key is disposed in the outer spacing.

6. The chip of claim 1, further comprising an outer spacing between the seal ring and the scribe line region, wherein half of the alignment key is disposed in the outer spacing, and the other half of the alignment key is disposed in the scribe line region.

7. The chip of claim 1, wherein the alignment key is disposed at a top surface or a bottom surface of the substrate.

8. The chip of claim 1, wherein the alignment key is spaced from the seal ring.

9. The chip of claim 1, wherein the alignment key is connected to the seal ring.

10. The chip of claim 1, wherein the scribe line region has a dicing edge, and the alignment key is spaced from the dicing edge.

11. The chip of claim 1, wherein the scribe line region has a dicing edge, and the alignment key is connected to the dicing edge.

12. A chip comprising:
a substrate having a top surface and a bottom surface; and
an alignment key disposed in the substrate and continuously extended from the top surface to the bottom surface in a single direction, wherein the alignment key is made of metal and is isolated from interconnection metal layers.

13. The chip of claim 12, wherein the alignment key comprises a triangle type pattern, a spiral type pattern, or a strip type pattern.

14. The chip of claim 12, wherein the alignment key comprises a plurality of dotted vias constructing a triangle type pattern, a spiral type pattern, or a strip type pattern.

15. The chip of claim 12, wherein the alignment key is a through-silicon via, a through glass-via, a through-InFO via, a though-molding via, or a though-dielectric via.

16. A package structure comprising:
a first device comprising a first alignment key on a top surface of the first device; and
a second device bonded on the first device and comprising a second alignment key on a bottom surface of the second device, wherein in a plan view, a plurality of pitches between the first alignment key and the second alignment key are identical, and the pitches are measured in at least two directions.

17. The package structure of claim 16, wherein the second alignment key is continuously extended from the bottom surface to a top surface of the second device in a single direction.

18. The package structure of claim 16, wherein the second device comprises an additional second alignment key disposed on a top surface the second device.

19. The package structure of claim 16, wherein the second device comprises:
a device region at a substrate;
a corner region at a corner of the substrate;
a seal ring surrounding the device region and comprising a corner section adjacent the corner region; and
a scribe line region surrounding the seal ring, wherein the second alignment key is disposed neighboring the corner section of the seal ring.

20. The package structure of claim 16, further comprising a third device bonded on the second device, the third device comprising a third alignment key on a surface of the third device, wherein in the plan view, a plurality of pitches between the second alignment key and the third alignment key are identical, and the pitches between the second alignment key and the third alignment key are measured in at least two directions.
